(19) United States
(12) Patent Application Publication
(10) Pub. No.: US 2019/0150297 A1
(43) Pub. Date: May 16, 2019

(54) PRINTED CIRCUIT BOARD, DISPLAY PANEL, DISPLAY DEVICE INCLUDING THE PRINTED CIRCUIT BOARD AND THE DISPLAY PANEL, AND METHOD OF MANUFACTURING THE DISPLAY DEVICE

(71) Applicant: Samsung Display Co., Ltd., Yongin-si (KR)

(72) Inventors: Young-jin KIM, Yongin-si (KR); Kiseok CHA, Suwon-si (KR); Ickkyu JANG, Yongin-si (KR); Yunmi KIM, Yongin-si (KR); Wonjong OHN, Seongnam-si (KR)

(21) Appl. No.: 16/143,670

(22) Filed: Sep. 27, 2018

(30) Foreign Application Priority Data
Nov. 16, 2017 (KR) 10-2017-0153369

(51) Int. Cl. H05K 3/36; G09F 9/30; G09G 3/20; H05K 1/18; H05K 3/32

(52) U.S. Cl. CPC H05K 3/361; G09F 9/301; H05K 2201/10128; H05K 1/189; H05K 3/32; G09G 3/20

(57) ABSTRACT

A display device includes a display panel that is curved in a direction surrounding an imaginary bending axis and has a top surface in which a plurality of panel bonding areas arranged in the curved direction is defined, a printed circuit board that is curved in the direction surrounding the bending axis and has a rear surface in which a plurality of board bonding areas arranged in the curved direction is defined, and a plurality of flexible circuit boards, each of which includes one end disposed on a corresponding one of the panel bonding areas so as to be connected to the display panel, and another end disposed on a corresponding one of the board bonding areas so as to be connected to the printed circuit board.

### CROSS-REFERENCE TO RELATED APPLICATION

This application claims priority under 35 U.S.C. § 119 to Korean Patent Application No. 10-2017-0153369, filed on Nov. 16, 2017, the disclosure of which is incorporated by reference herein in its entirety.

### TECHNICAL FIELD

Exemplary embodiments of the present invention relate to a display device and, more particularly, to a display device connected to a plurality of flexible circuit boards.

### DISCUSSION OF THE RELATED ART

Low-power and portable display devices are currently under development to meet desires of increased performance in display devices. A display device may include a thin film transistor disposed in each pixel and may turn each pixel on or off by using the thin film transistor.

In addition, the display device may include a display panel and a backlight unit providing light to the display panel. The backlight unit may include a light source and a light guide plate. Light generated from the light source may be guided in the light guide plate toward the display panel.

### SUMMARY

Embodiments of the invention may provide a display device capable of improving durability and reliability.

In an aspect of the invention, a display device may include a display panel that is curved in a direction surrounding an imaginary bending axis and has a top surface in which a plurality of panel bonding areas arranged in the curved direction are defined, a printed circuit board that is curved in the direction surrounding the bending axis and has a rear surface in which a plurality of board bonding areas arranged in the curved direction are defined, and a plurality of flexible circuit boards, each of which includes one end disposed on a corresponding one of the panel bonding areas so as to be connected to the display panel, and another end disposed on a corresponding one of the board bonding areas so as to be connected to the printed circuit board. At least one flexible circuit board, disposed at an outermost position, of the flexible circuit boards may be defined as an outermost flexible circuit board, and the outermost flexible circuit board may be tilted at a predetermined angle with the curved direction in such a way that the one end thereof is tilted with respect to the curved direction to face an outside of the display panel.

The printed circuit board may include a first surface in which the board bonding areas are defined, and a second surface opposite to the first surface. The printed circuit board may be disposed under the display panel, and the second surface may be closer to the display panel than the first surface.

At least the outermost flexible circuit board of the flexible circuit boards may be tilted at the predetermined angle with the curved direction in such a way that the another end thereof is tilted with respect to the curved direction to face an inside of the printed circuit board.

The flexible circuit boards may have the same shape and the same size.

The display panel may include a plurality of first pad electrodes disposed in each of other panel bonding areas of the panel bonding areas except at least one outermost panel bonding area, and a second pad electrode disposed in the outermost panel bonding area. An extending direction of the first pad electrodes may make the predetermined angle with an extending direction of the second pad electrode.

The printed circuit board may include a plurality of third pad electrodes disposed in each of other board bonding areas of the board bonding areas except an outermost board bonding area, and a fourth pad electrode disposed in the outermost board bonding area. An extending direction of the third pad electrodes may make the predetermined angle with an extending direction of the fourth pad electrode.

A magnitude of the predetermined angle may be in inverse proportion to a distance between the display panel and the bending axis.

The outermost flexible circuit board may be provided in plurality, and the outermost flexible circuit boards may be disposed symmetrically with respect to a central axis that is parallel to the bending axis and passes through a center of the display device.

Each of the flexible circuit boards may be tilted in such a way that the one end thereof is tilted with respect to the curved direction of the display panel to face the outside of the display panel and the another end thereof is tilted with respect to the curved direction of the printed circuit board to face the inside of the printed circuit board. The angle at which each of the flexible circuit boards is tilted in the order of being arranged in a direction from the outermost flexible circuit board toward the central axis is reduced.

In an aspect of the invention, a method of manufacturing a display device may include providing a display panel which has a flat plate shape and in which a plurality of panel bonding areas arranged in one direction is defined, providing a printed circuit board in which a plurality of board bonding areas arranged in the one direction is defined, connecting the display panel and the printed circuit board with a plurality of flexible circuit boards, disposing the printed circuit board under the display panel, and curving the display panel and the printed circuit board to surround an imaginary bending axis. The connecting of the display panel and the printed circuit board may include disposing one end of each of the flexible circuit boards on a corresponding one of the panel bonding areas, and disposing another end of each of the flexible circuit boards on a corresponding one of the board bonding areas. At least two outermost flexible circuit boards of the flexible circuit boards may be disposed to be tilted at a predetermined angle with the one direction in such a way that the one ends thereof are tilted with respect to the one direction to face an outside of the display panel and the other ends thereof are tilted with respect to the one direction to face an inside of the printed circuit board.

Areas of the panel bonding areas, on which the one ends of the outermost flexible circuit boards are disposed, may be defined as outermost panel bonding areas, and areas of the board bonding areas, on which the other ends of the outermost flexible circuit boards are disposed, may be defined as outermost board bonding areas. In the disposing of the printed circuit board under the display panel, a distance between each of the outermost panel bonding areas and a panel bonding area adjacent thereto may be equal to a distance between each of the outermost board bonding areas and a board bonding area adjacent thereto.

The printed circuit board may include a first surface in which the board bonding areas are defined, and a second surface opposite to the first surface. The disposing of the printed circuit board under the display panel may include disposing the printed circuit board in such a way that the second surface is closer to the display panel than the first surface.

The connecting of the display panel and the printed circuit board may include disposing the flexible circuit boards symmetrically with respect to a central axis that is parallel to the bending axis and passes through a center of the display device.

The connecting of the display panel and the printed circuit board may further include tilting the flexible circuit boards in such a way that the one ends of the flexible circuit boards are tilted to face the outside of the display panel and the other ends of the flexible circuit boards are tilted to face the inside of the printed circuit board. Tilted angles of the flexible circuit boards may sequentially decrease in a direction toward the central axis.

In an aspect of the invention, a display device may include a display panel displaying an image and including a pad area defined in one edge of the display panel in a first direction, the pad area including a plurality of panel bonding areas arranged in one direction intersecting the first direction, a printed circuit board in which a plurality of board bonding areas arranged in the one direction is defined and which is electrically connected to the display panel, and a plurality of flexible circuit boards, each of which includes one end disposed on a corresponding one of the panel bonding areas so as to be connected to the display panel, and another end disposed on a corresponding one of the board bonding areas so as to be connected to the printed circuit board. Each of at least two flexible circuit boards disposed at both ends in the one direction is tilted at a predetermined angle with a flexible circuit board adjacent thereto.

The display device may have a shape curved in a direction surrounding a bending axis parallel to the first direction.

The printed circuit board may be disposed under the display panel.

A magnitude of the predetermined angle may be in inverse proportion to a distance between the display panel and the bending axis.

Each of at least two panel bonding areas disposed at both ends among the panel bonding areas may be tilted in such a way that it becomes closer to an end of the one edge of the display panel in the first direction as a distance from each side of the display panel in the one direction decreases.

Panel bonding areas, disposed at both ends in the one direction, of the panel bonding areas may be defined as outermost panel bonding areas, and board bonding areas, disposed at both ends in the one direction, of the board bonding areas may be defined as outermost board bonding areas. A distance between each of the outermost panel bonding areas and a panel bonding area adjacent thereto may be equal to a distance between each of the outermost board bonding areas and a board bonding area adjacent thereto.

In an aspect of the invention, a display panel may include a plurality of pad electrodes disposed on one edge of the display panel in a first direction and arranged in a second direction perpendicular to the first direction. The pad electrodes may include a plurality of first pad electrodes arranged in the second direction, and at least one second pad electrode disposed at an outermost side of the first pad electrodes in the second direction. An extending direction of each of the first pad electrodes may be different from an extending direction of the second pad electrode.

In an aspect, a printed circuit board may include a plurality of pad electrodes disposed on one edge of the printed circuit board in a first direction and arranged in a second direction perpendicular to the first direction. The pad electrodes may include a plurality of third pad electrodes arranged in the second direction, and at least one fourth pad electrode disposed at an outermost side of the third pad electrodes in the second direction. An extending direction of each of the third pad electrodes may be different from an extending direction of the fourth pad electrode.

### BRIEF DESCRIPTION OF THE DRAWINGS

The above and other features of the present invention will become more apparent by describing in further detail exemplary embodiments thereof with reference to the accompanying drawings, in which:

FIG. 1 is an exploded perspective view illustrating a display device according to an exemplary embodiment of the present invention;

FIG. 2 is a perspective view illustrating a display module of FIG. 1 according to an exemplary embodiment of the present invention;

FIG. 3 is an enlarged view illustrating a bonding portion of a display panel and a printed circuit board according to an exemplary embodiment of the present invention;

FIG. 4 is an enlarged view of an area ‘A’ of FIG. 3 according to an exemplary embodiment of the present invention;

FIGS. 5A and 5B are cross-sectional views illustrating a display module according to an exemplary embodiment of the present invention;

FIGS. 6A and 6B are schematic views illustrating outermost flexible circuit boards when a display module is bent according to an exemplary embodiment of the present invention; and

FIG. 7 is an enlarged view illustrating a bonding portion of a display panel and a printed circuit board according to an exemplary embodiment of the present invention.

### DETAILED DESCRIPTION OF THE EMBODIMENTS

Exemplary embodiments of the present invention will be described more fully hereinafter with reference to the accompanying drawings. It is to be understood that the present invention may, however, be embodied in many different forms, and thus should not be construed as being limited to the exemplary embodiments set forth herein. In the figures, like reference numerals refer to like elements throughout.

It will be understood that when an element such as a layer, region or substrate is referred to as being “on” another element, the element may be directly on the other element or intervening elements.

In the drawings, sizes and thicknesses of layers and regions may be exaggerated for clarity. In addition, variations from the shapes, which are illustrated in the following figures, as a result, for example, of manufacturing techniques and/or tolerances, are to be expected. Thus, exemplary embodiments of the present invention should not be construed as limited to the shapes of regions illustrated herein but are to include deviations in shapes that result, for example, from manufacturing. For example, an etching region illustrated as a rectangle may, typically, have rounded or curved features.

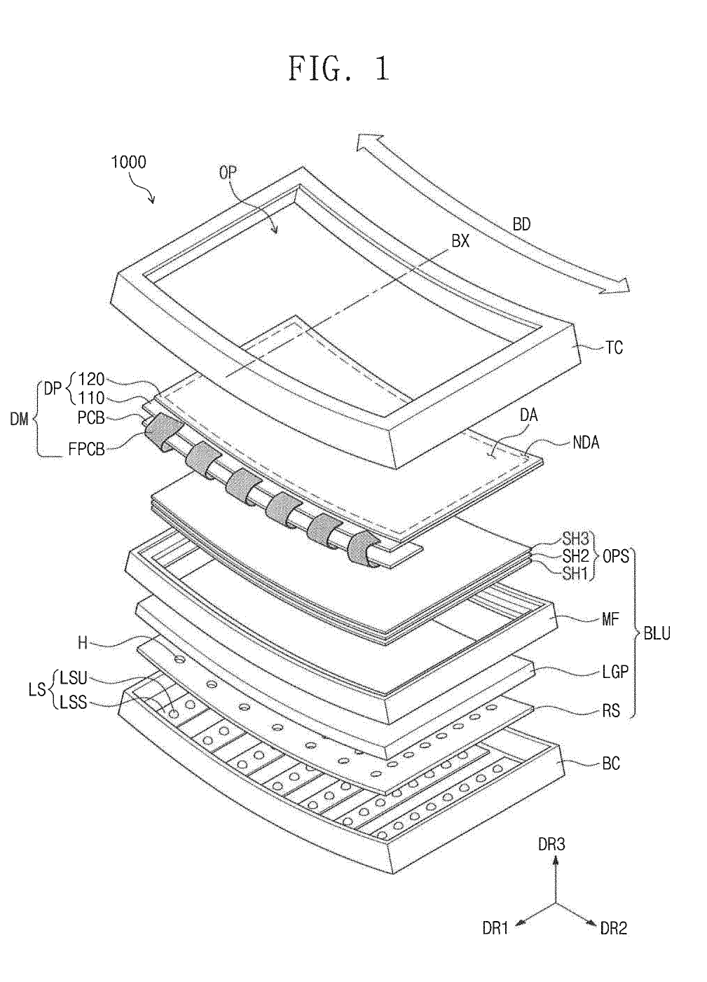

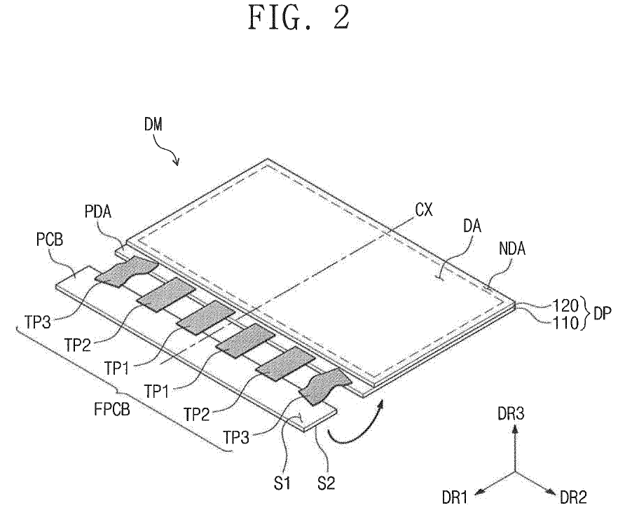

FIG. 1 is an exploded perspective view illustrating a display device according to an exemplary embodiment of the present invention, and FIG. 2 is a perspective view illustrating a display module of FIG. 1 according to an exemplary embodiment of the present invention. For the purpose of ease and convenience in the description, FIG. 2 illustrates a display module DM in an unbent or flat configuration.

Referring to FIGS. 1 and 2, a display device 1000 according to an exemplary embodiment of the present invention may have a rectangular shape that has short sides in a first direction DR1 and long sides in a second direction DR2. However, the present invention is not limited thereto. For example, the shape of the display device 1000 may have sides that are all equal in length or just two sides equal in length.

In the present embodiment, in the display device 1000, a direction in which an image is provided is an upward direction and a direction opposite to the upward direction is a downward direction. In the present embodiment, the upward and downward directions are parallel to a third direction DR3 perpendicular to the first direction DR1 and the second direction DR2. The third direction DR3 may be a reference direction that is used to indicate a front surface and a rear surface of each component described below. However, the upward and downward directions may be may be changed into other directions.

The display device 1000 may have a shape that is convexly bent in the downward direction from a plane indicated by the first and second directions DR1 and DR2. For example, the display device 1000 may be bent or curved in a concave direction toward the third direction DR3 with reference to a bending axis BX extending in the first direction DR1. Hereinafter, the concave direction BD is referred to as a bending direction BD. Therefore, the display device 1000 may have a straight line in the first direction DR1 and may have a curved line in a plane corresponding to the second and third directions DR2 and DR3.

The display device 1000 may include a display module DM, a backlight unit BLU, and a receiving member BC.

The display module DM may include a display panel DP, a printed circuit board PCB, and a plurality of flexible circuit boards FPCB.

The display panel DP may include at least one display surface for display an image. For example, one surface of the display panel includes a display area DA that displays an image and a non-display area NDA that does not display an image. In other words, the display panel DP may display an image through a concavely formed (e.g., curved or bent) display surface to provide a sense of immersion (or immersiveness) to a user.

The display area DA may be a central portion of the display surface of the display panel DP, and the non-display area NDA may have a frame shape surrounding the display area DA. However, exemplary embodiments of the present invention are not limited thereto. For example, a plurality of the display areas DA may be provided in the display surface of the display panel DP, and/or the non-display area NDA may be provided in only one or some edges of the display surface. In other words, the non-display area NDA may partially surround the display area DA.

In an exemplary embodiment of the present invention, a kind of the display panel DP used is not limited to a specific kind. For example, the display panel DP may be a liquid crystal display panel, an organic electro luminescence display panel, an electrowetting display panel, or a nano-crystal display panel. When the display panel DP is the organic electro luminescence display panel, the backlight unit BLU may be omitted in the display device 1000 since the organic electro luminescence display panel generates light by itself to display an image. Hereinafter, the liquid crystal display panel will be described as an example of the display panel DP in exemplary embodiments of the present invention.

The display panel DP may include a first substrate 110, a second substrate 120 facing the first substrate 110, and a liquid crystal layer disposed between the first substrate 110 and the second substrate 120.

The non-display area NDA may include a pad area PDA. The pad area PDA may be disposed on the first substrate 110. In the present embodiment, the pad area PDA may be disposed in one edge of the first substrate 110 extending in the first direction DR1 from the second substrate 120. For example, the one edge, in which the pad area PDA is disposed, may be exposed by the second substrate 120.

For example, in the present embodiment, a short side of the first substrate 110 may be longer than a short side of the second substrate 120. In other words, a size of the first substrate 110 may be greater than a size of the second substrate 120, and a portion of the first substrate 110 may be exposed by the second substrate 120. Another edge of the first substrate 110 in the first direction DR1 may be covered by the second substrate 120. In other words, a remaining portion of the first substrate 110 except the one edge of the first substrate 110, exposed by the second substrate 120, may overlap with the second substrate 120. An area in which the first and second substrates 110 and 120 overlap with each other may include the display area DA. The pad area PDA may be provided in an area in which the first and second substrates 110 and 120 do not overlap with each other.

The printed circuit board PCB may extend along the long side of the display device 1000. The printed circuit board PCB may have a shape that is convexly bent in the downward direction from the plane defined by the first and second directions DR1 and DR2. The printed circuit board PCB may be disposed under the display panel DP to overlap with one edge of the display panel DP in the third direction DR3. For example, the printed circuit board PCB may overlap with the pad area PDA, which extends in the first direction DR1 from the second substrate 120.

The printed circuit board PCB may include a first surface S1 and a second surface S2 opposite to the first surface S1 in the third direction DR3. The printed circuit board PCB may be disposed under the display panel DP in such a way that the second surface S2 is closer to the display panel DP than the first surface S1. For example, the first surface S1 may be a bottom surface (e.g., rear surface) and the second surface S2 may be a top surface.

The flexible circuit boards FPCB may electrically connect the display panel DP and the printed circuit board PCB to each other. The flexible circuit boards FPCB may be flexible and may be bent so that the printed circuit board PCB may be disposed under the display panel DP. In the present embodiment, the flexible circuit boards FPCB may be provided in the form of a tape carrier package (TCP).

For example, one end of each of the flexible circuit boards FPCB may be connected to the pad area PDA of the display panel DP, and another end of each of the flexible circuit boards FPCB may be connected to the printed circuit board PCB.

According to the present embodiment, the display panel DP and the printed circuit board PCB may be connected to each other by the flexible circuit boards FPCB, and then, the flexible circuit boards FPCB may be bent downward so that the printed circuit board PCB may be disposed under the display panel DP. In addition, in an exemplary embodiment of the present invention, the printed circuit board PCB may be disposed under the display panel DP, and then, the display panel DP and the printed circuit board PCB may be connected to each other by the flexible circuit boards FPCB.

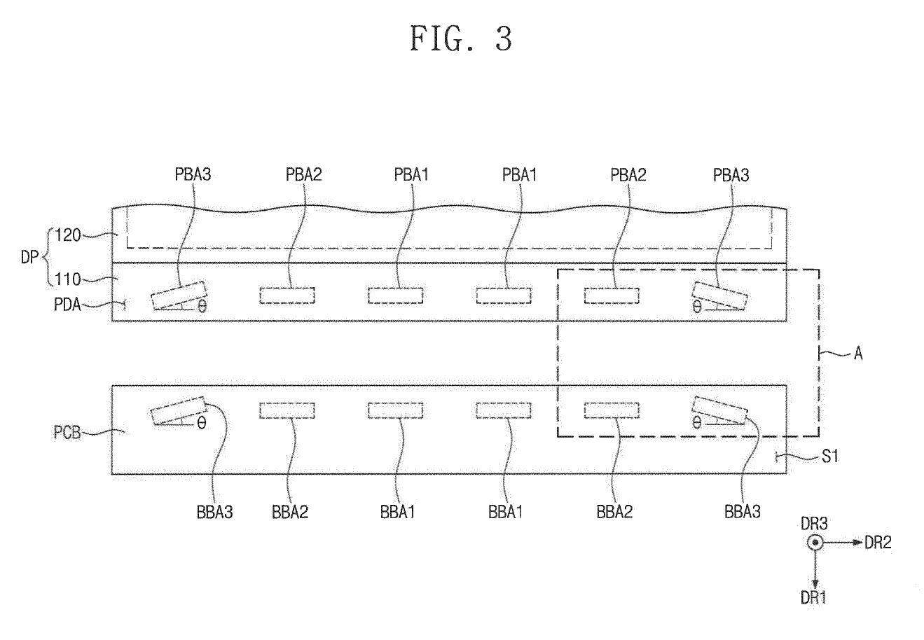

The display module DM will be described later with reference to FIGS. 3 to 6B.

The backlight unit BLU may provide light to the display panel DP and may be disposed under the display panel DP. The backlight unit BLU may include a light source LS, a light guide plate LGP, optical sheets OPS, and a reflective sheet RS.

The light source LS may generate light. In an exemplary embodiment of the present invention, the backlight unit BLU may be a direct type backlight unit. However, exemplary embodiments of the present invention are not limited thereto.

The light source LS may include a plurality of light source units LSU and a plurality of light source substrates LSS. Each of the light source substrates LSS may have a rectangular plate shape extending in the first direction DR1. The light source substrates LSS may be arranged in the second direction DR2. However, exemplary embodiments of the present invention are not limited to the number, the extending direction, the arrangement direction and the shapes of the light source substrates LSS.

The light source units LSU may be mounted on each of the light source substrates LSS. The light source units LSU may be arranged in the extending direction of each of the light source substrates LSS. For example, the light source units LSU may be arranged in the first direction DR1.

The light guide plate LGP may be disposed over the light source LS. The light guide plate LGP may have a shape that is convexly bent in the downward direction parallel to the third direction DR3.

The light guide plate LGP may receive light from the light source LS and may guide the received light toward the display panel DP. The light guide plate LGP may include a material that has a high light transmittance in a visible light band. The light guide plate LGP may be formed of at least one of, but not limited to, polyamide (PA), polymethyl methacrylate (PMMA), methyl methacrylate-styrene (MS), or polycarbonate (PC). In an exemplary embodiment of the present invention, the light guide plate LGP may be omitted.

The optical sheets OPS may be disposed between the light guide plate LGP and the display panel DP. The optical sheets OPS may control a path of the light guided from the light guide plate LGP. The optical sheets OPS may have shapes that are convexly bent in the downward direction.

The optical sheets OPS may include a diffusion sheet SH1, a prism sheet SH2, and a protective sheet SH3. The diffusion sheet SH1 may diffuse light. The prism sheet SH2 may condense the light diffused by the diffusion sheet SH1 in such a way that traveling directions of the diffused light become closer to a normal direction of the display panel DP (e.g., a perpendicular to the display panel DP). The protective sheet SH3 may protect the prism sheet SH2 from an external impact. In the present embodiment, the optical sheets OPS include one diffusion sheet SH1, one prism sheet SH2, and one protective sheet SH3. However, exemplary embodiments of the present invention are not limited thereto. In an exemplary embodiment of the present invention, at least one of the diffusion sheet SH1, the prism sheet SH2 or the protective sheet SH3 may be provided in plurality, or one or more of the diffusion sheet SH1, the prism sheet SH2 and the protective sheet SH3 may be omitted.

The reflective sheet RS may be disposed between the light source LS and the light guide plate LGP. The reflective sheet RS may have a shape that is convexly bent in the downward direction.

The reflective sheet RS may reflect light leaked from the light guide plate LGP to provide the leaked light to the light guide plate LGP. The reflective sheet RS may include a plurality of holes H. The light source units LSU may be inserted in the holes H.

The backlight unit BLU according to an exemplary embodiment of the present invention may include a mold frame MF. The mold frame MF may be provided along edges of the display panel DP to support the display panel DP from beneath it. In other words, the mold frame MF may have a ring shape or a rectangular shape with an opening in the center thereof. In addition, the mold frame MF may support the optical sheets OPS disposed under the display panel DP.

The receiving member BC may be disposed at a bottom of the display device 1000 to receive the display panel DP and the backlight unit BLU. The receiving member BC may have a shape that is convexly bent in the downward direction. The light source LS may be disposed on a bottom portion of the receiving member BC. The receiving member BC may be made of a metal material.

The display device 1000 according to an exemplary embodiment of the present invention may further include a protective member TC. The protective member TC may be disposed above the display device 1000. The protective member TC may have a shape that is convexly bent in the downward direction. The protective member TC may have a frame shape extending along the edges of the display panel DP. In other words, an opening OP in the protective member TC may overlap the display area DA and the protective member TC may surround the display panel DP. The display area DA of the display panel DP may be exposed through the opening OP. In an exemplary embodiment of the present invention, the protective member TC may be omitted.

In the present embodiment, the display panel DP and the printed circuit board PCB connected to each other by the flexible circuit boards FPCB may have shapes which are curved along the bending axis BX. The display panel DP and the printed circuit board PCB may be curved by external pressure. For example, when the display device 1000 is assembled, the display panel DP and the printed circuit board PCB may be provided in a curved state by the curved shapes of the protective member TC, the receiving member BC and the mold frame MF which may have a high hardness or rigidity.

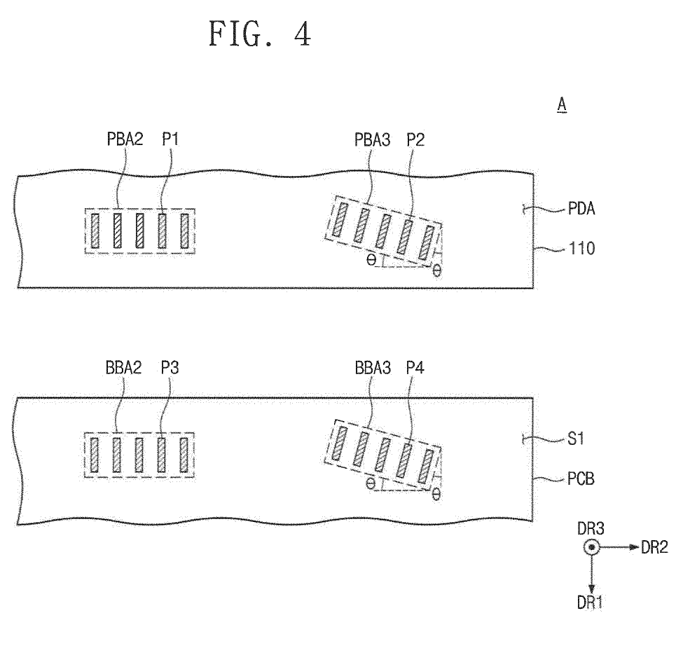

FIG. 3 is an enlarged view illustrating a bonding portion of a display panel and a printed circuit board according to an exemplary embodiment of the present invention. FIG. 4 is an enlarged view of an area ‘A’ of FIG. 3 according to an exemplary embodiment of the present invention. For the purpose of ease and convenience in description, FIGS. 2 to 4 illustrate the display module DM in a flat, unbent, or un-curved configuration. For example, in FIG. 2, the printed circuit board PCB is disposed adjacent to the display panel DP and the flexible circuit boards FPCB are stretched out. In addition, for the purpose of ease and convenience in description, the first surface S1 of the printed circuit board PCB is illustrated in FIGS. 3 and 4.

Referring to FIGS. 2 to 4, the pad area PDA of the display panel DP may include a plurality of panel bonding areas PBA1 to PBA3. The panel bonding areas PBA1 to PBA3 may be arranged in the second direction DR2 in a plane parallel to the first and second directions DR1 and DR2.

The panel bonding areas PBA1 to PBA3 may be arranged in the second direction DR2 before the display panel DP is curved from a flat configuration. However, after the assembly of the display device 1000 is completed, the panel bonding areas PBA1 to PBA3 of the curved display panel DP may be arranged in the bending direction BD (see FIG. 1). The panel bonding areas PBA1 to PBA3, after the display panel DP, is curved will be described later.

The panel bonding areas PBA1 to PBA3 may be arranged symmetrically with respect to a central axis CX that is parallel to the bending axis BX and passes through a center of the display device 1000. In other words, the number of panel bonding areas PBA1 to PBA3 on one side of the central axis CX is the same as the number of panel bonding areas PBA1 to PBA3 on the other side of the central axis CX.

For example, the panel bonding areas PBA1 to PBA3 may include first panel bonding areas PBA1, second panel bonding areas PBA2, and third panel bonding areas PBA3. One first panel bonding area PBA1, one second panel bonding area PBA2 and one third panel bonding area PBA3 may be disposed in the pad area PDA at each side of the central axis CX.

Six panel bonding areas PBA1 to PBA3 are illustrated in FIGS. 2 and 3. However, exemplary embodiments of the of the present invention are not limited to the number of the panel bonding areas PBA1 to PBA3. In an exemplary embodiment of the present invention, even though not shown in the drawings, an odd number of the panel bonding areas may be provided. In this case, a panel bonding area disposed at a center may overlap with the central axis CX, and the other panel bonding areas may be arranged symmetrically with respect to the panel bonding area disposed at the center.

The first, second and third panel bonding areas PBA1, PBA2 and PBA3 disposed at each side of the central axis CX may be sequentially arranged in a direction away from the central axis CX. For example, the first panel bonding areas PBA1 may be disposed closer to the central axis CX than the second panel bonding areas PBA2. The second panel bonding areas PBA2 may be disposed closer to the central axis CX than the third panel bonding areas PBA3. In other words, the third panel bonding areas PBA3 may correspond to the outermost panel bonding areas of the panel bonding areas PBA1 to PBA3 in the second direction DR2. Hereinafter, the third panel bonding areas PBA3 are the outermost panel bonding areas.

In the present embodiment, each of the panel bonding areas PBA1 to PBA3 may have a rectangular shape. For example, in the present embodiment, each of the first panel bonding areas PBA1 and the second panel bonding areas PBA2 may have a rectangular shape having a long side parallel to the second direction DR2. However, exemplary embodiments of the present invention are not limited to the shapes of the panel bonding areas PBA1 to PBA3.

Each of the outermost panel bonding areas PBA3 may be tilted with respect to the second direction DR2 to face the outside of the display panel DP. In other words, each of the outermost panel bonding areas PBA3 may be tilted in such a way that it becomes closer to an end of the one edge of the display panel DP in the first direction DR1 as a distance in the second direction DR2 from each short side of the display panel DP decreases.

Each of the outermost panel bonding areas PBA3 may be tilted at a predetermined angle θ with respect to the second direction DR2. In other words, each of the outermost panel bonding areas PBA3 may have a rectangular shape having a long side tilted at the predetermined angle θ with respect to the second direction DR2. The outermost panel bonding areas PBA3 may be tilted symmetrically with respect to the central axis CX.

In the present embodiment, two outermost panel bonding areas PBA3 are disposed on the display panel DP. However, exemplary embodiments of the present invention are not limited to the number of the outermost panel bonding areas PBA3. For example, in an exemplary embodiment of the present invention, one outermost panel bonding area may be disposed at one of two ends of the panel bonding areas PBA1 to PBA3.

The display panel DP may include a plurality of pad electrodes P1 or P2 disposed in each of the panel bonding areas PBA1 to PBA3 and arranged in a long side direction of each of the panel bonding areas PBA1 to PBA3.

First pad electrodes P1 may be disposed in each of the first and second panel bonding areas PBA1 and PBA2. The first pad electrodes P1 may extend in the first direction DR1. Second pad electrodes P2 may be disposed in each of the outermost panel bonding areas PBA3. The second pad electrodes P2 may make the predetermined angle θ with respect to the first pad electrodes P1. However, exemplary embodiments of the present invention are not limited to the extending directions and the shapes of the pad electrodes P1 and P2.

The printed circuit board PCB may include a plurality of board bonding areas BBA1 to BBA3 defined in the first surface S1 of the printed circuit board PCB. The board bonding areas BBA1 to BBA3 may be arranged in the second direction DR2 in a plane parallel to the first and second directions DR1 and DR2.

The board bonding areas BBA1 to BBA3 may be arranged in the second direction DR2 before the printed circuit board PCB is curved from a flat configuration. However, after the assembly of the display device 1000 is completed, the board bonding areas BBA1 to BBA3 of the curved printed circuit board PCB may be arranged in the bending direction BD (see FIG. 1). The board bonding areas BBA1 to BBA3, after the printed circuit board PCB is curved, will be described later.

The board bonding areas BBA1 to BBA3 may be arranged symmetrically with respect to the central axis CX that is parallel to the bending axis BX and passes through the center of the display device 1000. In other words, the number of board bonding areas BBA1 to BBA3 on one side of the central axis CX is the same as the number of board bonding areas BBA1 to BBA3 on the other side of the central axis CX.

For example, the board bonding areas BBA1 to BBA3 may include first board bonding areas BBA1, second board bonding areas BBA2, and third board bonding areas BBA3. One first board bonding area BBA, one second board bonding area BBA2 and one third board bonding area BBA3 may be disposed in the printed circuit board PCB at each side of the central axis CX. The board bonding areas BBA1 to BBA3 may correspond one-to-one to the panel bonding areas PBA1 to PBA3.

Six board bonding areas BBA1 to BBA3 are illustrated in FIGS. 2 and 3. However, exemplary embodiments of the present invention are not limited to the number of the board bonding areas BBA1 to BBA3. In an exemplary embodiment of the present invention, an odd number of the board bonding areas may be disposed in the printed circuit board PCB. In this case, a board bonding area disposed at a center may overlap with the central axis CX, and the other board bonding areas may be arranged symmetrically with respect to the board bonding area disposed at the center.

The first, second and third board bonding areas BBA1, BBA2 and BBA3 disposed at each side of the central axis CX may be sequentially arranged in a direction away from the central axis CX. For example, the first board bonding areas BBA1 may be disposed closer to the central axis CX than the second board bonding areas BBA2. The second board bonding areas BBA2 may be disposed closer to the central axis CX than the third board bonding areas BBA3. In other words, the third board bonding areas BBA3 may correspond to the outermost board bonding areas of the board bonding areas BBA1 to BBA3 in the second direction DR2. Hereinafter, the third board bonding areas BBA3 are the outermost board bonding areas.

In the present embodiment, each of the board bonding areas BBA1 to BBA3 may have a rectangular shape. For example, in the present embodiment, each of the first board bonding areas BBA1 and the second board bonding areas BBA2 may have a rectangular shape having a long side parallel to the second direction DR2. However, exemplary embodiments of the present invention are not limited to the shapes of the board bonding areas BBA1 to BBA3. For example, the board bonding areas BBA1 to BBA3 may have square or rounded shape.

Each of the outermost board bonding areas BBA3 may be tilted with respect to the second direction DR2 to face the inside of the printed circuit board PCB. In other words, each of the outermost board bonding areas BBA3 may be tilted in such a way that it becomes closer to a side, connected to the display panel DP, of sides of the printed circuit board PCB facing each other in the first direction DR1 as a distance between the central axis CX and the outermost board bonding areas BBA3 on the first surface S1 decreases.

The printed circuit board PCB may include a plurality of pad electrodes P3 or P4 disposed in each of the board bonding areas BBA1 to BBA3 and arranged in a long side direction of each of the board bonding areas BBA1 to BBA3. For example, the pad electrode P3 or P4 are arranged in the second direction DR2.

Third pad electrodes P3 may be disposed in each of the first and second board bonding areas BBA1 and BBA2. The third pad electrodes P3 may extend in the first direction DR1. Fourth pad electrodes P4 may be disposed in each of the outermost board bonding areas BBA3. The fourth pad electrodes P4 may make the predetermined angle θ with the third pad electrodes P3. However, exemplary embodiments of the present invention are not limited to the extending directions and the shapes of the pad electrodes P3 and P4.

The flexible circuit boards FPCB may electrically connect the display panel DP and the printed circuit board PCB to each other. The flexible circuit boards FPCB (TP1 to TP3) may be arranged in the second direction DR2. For example, flexible circuit boards FPCB (TP1 to TP3) may be arranged symmetrically with respect to the central axis CX in the second direction DR2.

The flexible circuit boards FPCB may be arranged in the second direction DR2 before the display module DM is formed into a curved configuration. However, after the assembly of the display device 1000 is completed, the flexible circuit boards FPCB of the curved display module DM may be arranged in the bending direction BD (see FIG. 1). The flexible circuit boards FPCB after the display module DM is curved will be described later.

The flexible circuit boards FPCB may be provided to correspond to the number of the panel bonding areas PBA1 to PBA3 provided on the display panel DP and the number of the board bonding areas BBA1 to BBA3 provided on the printed circuit board PCB. For example, the flexible circuit boards FPCB may include first flexible circuit boards TP1, second flexible circuit boards TP2, and third flexible circuit boards TP3. One first flexible circuit board TP1, one second flexible circuit board TP2 and one third flexible circuit board TP3 may be disposed at each side of the central axis CX.

The first, second and third flexible circuit boards TP1, TP2 and TP3 disposed at each side of the central axis CX may be sequentially arranged in a direction away from the central axis CX. The first flexible circuit boards TP1 may be disposed closer to the central axis CX than the second flexible circuit boards TP2. The second flexible circuit boards TP2 may be disposed closer to the central axis CX than the third flexible circuit boards TP3. In other words, the third flexible circuit boards TP3 may be the outermost flexible circuit boards of the flexible circuit boards TP1 to TP3 arranged in the second direction DR2. Hereinafter, the third flexible circuit boards TP3 is the outermost flexible circuit boards TP3.

In the present embodiment, the flexible circuit boards TP1 to TP3 may have substantially the same shape and substantially the same size. For example, the flexible circuit boards TP1 to TP3 may have rectangular shapes. However, exemplary embodiments of the present invention are not limited thereto. For example, the flexible circuit boards TP1 to TP3 may have a square shape.

The flexible circuit boards TP1 to TP3 may correspond to the panel bonding areas PBA1 to PBA3 and the board bonding areas BBA1 to BBA3, respectively. One end of each of the flexible circuit boards TP1 to TP3 may be disposed on a corresponding one of the panel bonding areas PBA1 to PBA3 to be connected to the display panel DP, and another end of each of the flexible circuit boards TP1 to TP3 may be disposed on a corresponding one of the board bonding areas BBA1 to BBA3 to be connected to the printed circuit board PCB.

For example, the first and second flexible circuit boards TP1 and TP2 may extend in parallel to the first direction DR1 to electrically connect the display panel DP and the printed circuit board PCB.

Each of the outermost flexible circuit boards TP3 may be tilted at the predetermined angle θ with the second direction DR2 in such a way that the one end thereof is tilted with respect to the second direction DR2 to face the outside of the display panel DP. In other words, each of the outermost flexible circuit boards TP3 may be tilted at the predetermined angle θ in such a way that the other end thereof faces the inside of the printed circuit board PCB. In the present embodiment, the predetermined angle θ may be in inverse proportion to a radius of curvature of the curved display module DM. In other words, the predetermined angle θ may be in inverse proportion to a distance between the display module DM and the imaginary bending axis BX (see FIG. 1).

Since the one end and the other end of each of the flexible circuit boards TP1 to TP3 are disposed on the corresponding one of the panel bonding areas PBA1 to PBA3 and the corresponding one of the board bonding areas BBA1 to BBA3, respectively, the display panel DP may be electrically connected to the printed circuit board PCB. In other words, the third pad electrodes P3 may be electrically connected to the first pad electrodes P1 through the flexible circuit boards TP1 and TP2, and the fourth pad electrodes P4 may be electrically connected to the second pad electrodes P2 through the outermost flexible circuit boards TP3.

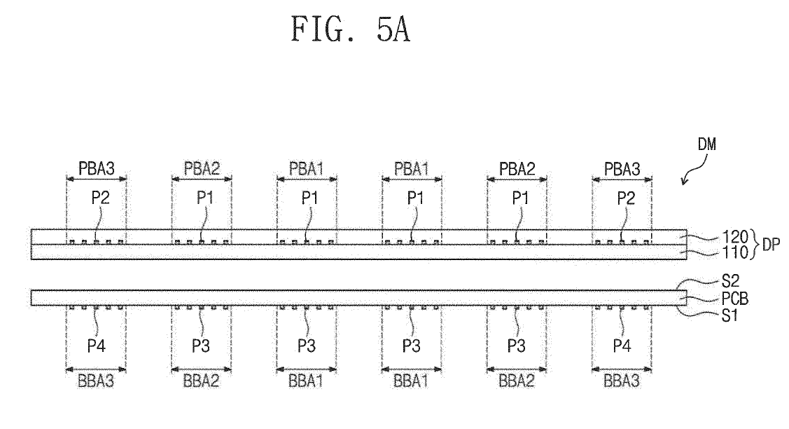

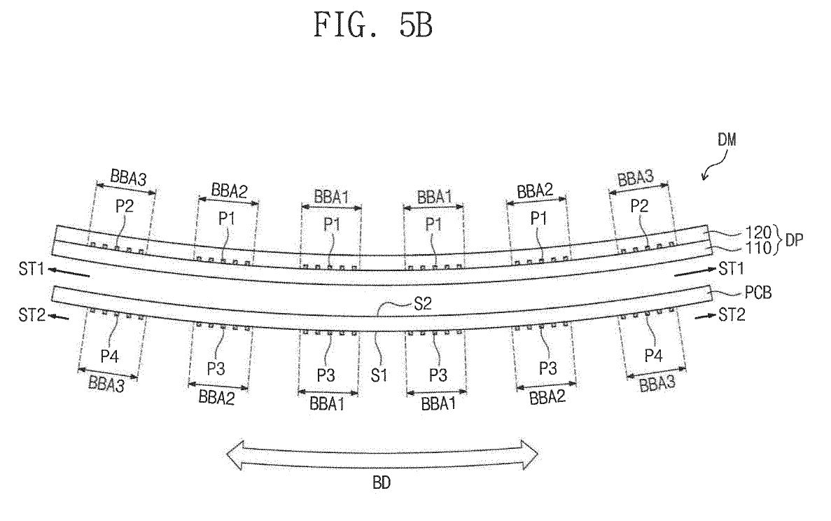

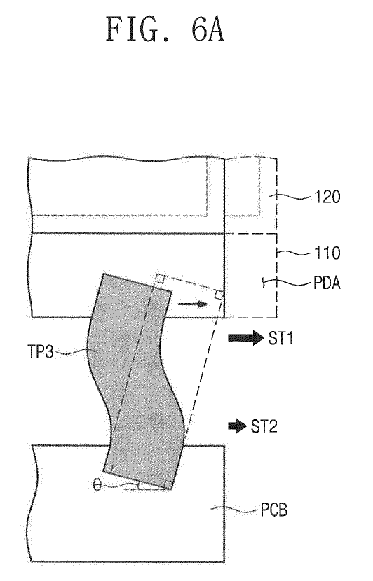

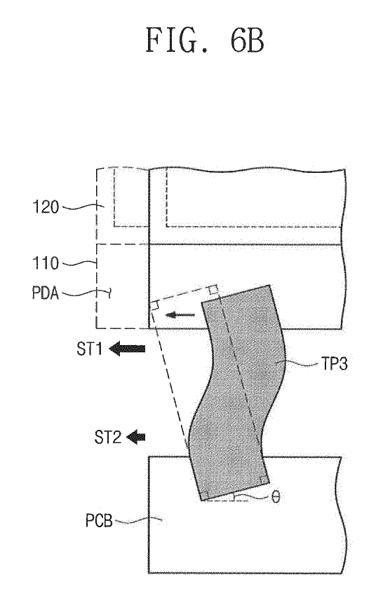

FIGS. 5A and 5B are cross-sectional views illustrating a display module according to an exemplary embodiment of the present invention, and FIGS. 6A and 6B are schematic views illustrating outermost flexible circuit boards when a display module is bent according to an exemplary embodiment of the present invention. For example, FIG. 5A illustrates a state before the display module DM is curved (e.g., when the display module DM is in a flat state), and FIG. 5B illustrates a state after the display module DM is curved. The flexible circuit boards FPCB are omitted in FIGS. 5A and 5B for the purpose of ease and convenience in description and illustration. In addition, FIGS. 6A and 6B illustrate a position of the display panel with respect to the printed circuit board when the display module DM is curved.

As illustrated in FIG. 5A, before the display module DM is curved, the panel bonding areas PBA1 to PBA3 may overlap with the board bonding areas BBA1 to BBA3 when viewed from a cross-sectional view.

In addition, before the display module DM is curved, a distance between the outermost panel bonding area PBA3 and the second panel bonding area PBA2 may be equal to a distance between the outermost board bonding area BBA3 and the second board bonding area BBA2. For example, a radius of curvature of the printed circuit board PCB may correspond to a radius of curvature of the display panel DP.

Referring to FIGS. 5B, 6A and 6B, the display module DM may be curved in the bending direction BD by external pressure. Since the display module DM is curved, the display panel DP may be moved away from the printed circuit board PCB. For example, since the display module DM is curved, a separation distance between a point in the panel bonding areas PBA1 to PBA3 and a corresponding point in the board bonding areas BBA1 to BBA3 may increase.

An increasing rate of the separation distance may increase as a distance from the central axis CX (see FIG. 2) increases. In addition, the increasing rate of the separation distance may be in inverse proportion to the distance between the display module DM and the bending axis BX (see FIG. 1).

Unlike the embodiment of the invention, if all the flexible circuit boards FPCB are disposed in parallel to each other (e.g., the outermost panel bonding areas PBA3 are parallel to the second direction DR2 and the outermost board bonding areas BBA3 are parallel to the second direction DR2), stress may occur at the flexible circuit boards FPCB by the increase in the separation distance which is caused by the curving of the display module DM. Therefore, damage may occur at the outermost flexible circuit boards TP3 having the highest increasing rate of the separation distance, and/or the connection between the display panel DP and the printed circuit board PCB may be broken. However, according to an exemplary embodiment of the present invention, since the outermost flexible circuit boards TP3 are tilted with respect to the second direction DR2 to face the outside of the display panel DP, the increase in the separation distance by the curving of the display module DM may be compensated. In other words, the connection between the display panel DP and the printed circuit board PCB may be prevented from being broken.

As a result, according to an exemplary embodiment of the present invention, durability of the display device 1000 may be increased.

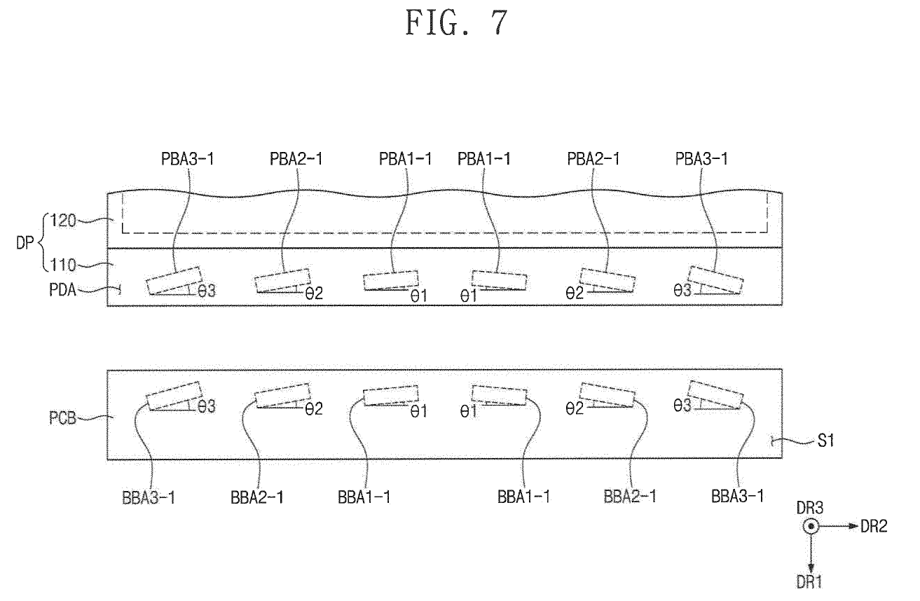

FIG. 7 is an enlarged view illustrating a bonding portion of a display panel and a printed circuit board according to an exemplary embodiment of the present invention.

For the purpose of ease and convenience in description, differences between the present embodiment and the above exemplary embodiments of the present invention will be mainly described and the same descriptions as in the above exemplary embodiments of the present invention may be omitted. In addition, the same components as described above may be indicated by the same reference designators, and the descriptions thereto may be omitted or mentioned briefly.

As illustrated in FIG. 7, according to an exemplary embodiment of the present invention, one first panel bonding area PBA1-1, one second panel bonding area PBA2-1 and one third panel bonding area PBA3-1 may be disposed in the pad area PDA at each side of the central axis CX.

In addition, one first board bonding area BBA1-1, one second board bonding area BBA2-1 and one third board bonding area BBA3-1 may be disposed in the printed circuit board PCB at each side of the central axis CX. The board bonding areas BBA1-1 to BBA3-1 may correspond one-to-one to the panel bonding areas PBA1-1 to PBA3-1.

According to the present embodiment, tilted angles of the panel bonding areas PBA1-1 to PBA3-1 and tilted angles of the board bonding areas BBA1-1 to BBA3-1 may sequentially decrease in a direction toward the central axis CX.

For example, the first panel bonding areas PBA1-1 and the first board bonding areas BBA1-1 may be tilted at a first angle θ1 with respect to the second direction DR2. The second panel bonding areas PBA2-1 and the second board bonding areas BBA2-1 may be tilted at a second angle θ2 with respect to the second direction DR2. The third panel bonding areas PBA3-1 and the third board bonding areas BBA3-1 may be tilted at a third angle θ3 with respect to the second direction DR2. A magnitude of the second angle θ2 may be greater than a magnitude of the first angle θ1. A magnitude of the third angle θ3 may be greater than a magnitude of the second angle θ2. For example, tilted angles of the flexible circuit boards disposed at each side of the central axis CX may sequentially decrease in a direction from the outermost flexible circuit board disposed at each side of the central axis CX toward the central axis CX. The tilted angle may be in proportion to the separation distance described above.

In an exemplary embodiment of the present invention, the third panel bonding areas PBA3-1 and the third board bonding areas BBA3-1 may be titled at the third angle θ3. The second panel bonding areas PBA2-1 and the second board bonding areas BBA2-1 may be titled at the second angle θ2, but the first panel bonding areas PBA1-1 and the first board bonding areas BBA1-1 may not be tilted at a predetermined angle. However, the present invention is not limited thereto.

According to exemplary embodiments of the present invention, the durability and reliability of the display device may be increased.

While the present invention has been described with reference to exemplary embodiments thereof, it will be understood by those of ordinary skill in the art that various changes in form and details may be made thereto without departing from the spirit and scope of the present invention as defined by the following claims.

What is claimed is:

1. A display device comprising:
a display panel that is curved in a direction surrounding an imaginary bending axis and has a top surface in which a plurality of panel bonding areas arranged in the curved direction are defined;
a printed circuit board that is curved in the direction surrounding the bending axis and has a rear surface in which a plurality of board bonding areas arranged in the curved direction are defined; and
a plurality of flexible circuit boards, each of which includes: one end disposed on a corresponding one of the panel bonding areas so as to be connected to the display panel; and another end disposed on a corresponding one of the board bonding areas so as to be connected to the printed circuit board,
wherein at least one flexible circuit board, disposed at an outermost position, of the flexible circuit boards is defined as an outermost flexible circuit board, and
wherein the outermost flexible circuit board is tilted at a predetermined angle with the curved direction in such a way that the one end thereof is tilted with respect to the curved direction to face an outside of the display panel.

2. The display device of claim 1, wherein the printed circuit board comprises:
a first surface in which the board bonding areas are defined; and
a second surface opposite to the first surface,
wherein the printed circuit board is disposed under the display panel, and
wherein the second surface is closer to the display panel than the first surface.

3. The display device of claim 2, wherein at least the outermost flexible circuit board of the flexible circuit boards is tilted at the predetermined angle with the curved direction in such a way that the another end thereof is tilted with respect to the curved direction to face an inside of the printed circuit board.

4. The display device of claim 3, wherein the flexible circuit boards have the same shape and the same size.

5. The display device of claim 1, wherein wherein at least one panel bonding area, disposed at an outermost position, of the panel bonding areas is defined as an outermost panel bonding area, and the display panel comprises:
a plurality of first pad electrodes disposed in each of other panel bonding areas of the panel bonding areas except at least the outermost panel bonding area; and
a second pad electrode disposed in the outermost panel bonding area,
wherein an extending direction of the first pad electrodes makes the predetermined angle with an extending direction of the second pad electrode.

6. The display device of claim 1, wherein wherein at least one board bonding area, disposed at an outermost position, of the board bonding areas is defined as an outermost board bonding area, and the printed circuit board comprises:
a plurality of third pad electrodes disposed in each of other board bonding areas of the board bonding areas except the outermost board bonding area; and
a fourth pad electrode disposed in the outermost board bonding area,
wherein an extending direction of the third pad electrodes makes the predetermined angle with an extending direction of the fourth pad electrode.

7. The display device of claim 1, wherein a magnitude of the predetermined angle is in inverse proportion to a distance between the display panel and the bending axis.

8. The display device of claim 1, wherein the outermost flexible circuit board is provided in plurality, and
wherein the outermost flexible circuit boards are disposed symmetrically with respect to a central axis that is parallel to the bending axis and passes through a center of the display device.

9. The display device of claim 8, wherein each of the flexible circuit boards is tilted in such a way that the one end thereof is tilted with respect to the curved direction of the display panel to face the outside of the display panel and the another end thereof is tilted with respect to the curved direction of the printed circuit board to face the inside of the printed circuit board, and
wherein the angle at which each of the flexible circuit boards is tilted in the order of being arranged in a direction from the outermost flexible circuit board toward the central axis is reduced.

10. A method of manufacturing a display device, the method comprising:
providing a display panel which has a flat plate shape and in which a plurality of panel bonding areas arranged in one direction is defined;
providing a printed circuit board in which a plurality of board bonding areas arranged in the one direction is defined;
connecting the display panel and the printed circuit board with a plurality of flexible circuit boards;
disposing the printed circuit board under the display panel; and
curving the display panel and the printed circuit board to surround an imaginary bending axis,
wherein the connecting of the display panel and the printed circuit board comprises:
disposing one end of each of the flexible circuit boards on a corresponding one of the panel bonding areas; and
disposing another end of each of the flexible circuit boards on a corresponding one of the board bonding areas,
wherein at least two outermost flexible circuit boards of the flexible circuit boards are disposed to be tilted at a predetermined angle with the one direction in such a way that the one ends thereof are tilted with respect to the one direction to face an outside of the display panel and the other ends thereof are tilted with respect to the one direction to face an inside of the printed circuit board.

11. The method of claim 10, wherein areas of the panel bonding areas, on which the one ends of the outermost flexible circuit boards are disposed, are defined as outermost panel bonding areas,
wherein areas of the board bonding areas, on which the other ends of the outermost flexible circuit boards are disposed, are defined as outermost board bonding areas, and
wherein, in the disposing of the printed circuit board under the display panel, a distance between each of the outermost panel bonding areas and a panel bonding area adjacent thereto is equal to a distance between each of the outermost board bonding areas and a board bonding area adjacent thereto.

12. The method of claim 11, wherein the printed circuit board includes: a first surface in which the board bonding areas are defined; and a second surface opposite to the first surface,
wherein the disposing of the printed circuit board under the display panel comprises:
disposing the printed circuit board in such a way that the second surface is closer to the display panel than the first surface.

13. The method of claim 11, wherein the connecting of the display panel and the printed circuit board comprises: disposing the flexible circuit boards symmetrically with respect to a central axis that is parallel to the bending axis and passes through a center of the display device.

14. The method of claim 13, wherein the connecting of the display panel and the printed circuit board further comprises:
tilting the flexible circuit boards in such a way that the one ends of the flexible circuit boards are tilted to face the outside of the display panel and the other ends of the flexible circuit boards are tilted to face the inside of the printed circuit board,
wherein tilted angles of the flexible circuit boards sequentially decrease in a direction toward the central axis.

15. A display device comprising:
a display panel displaying an image and including a pad area defined in one edge of the display panel in a first direction, wherein the pad area includes a plurality of panel bonding areas arranged in one direction intersecting the first direction;
a printed circuit board in which a plurality of board bonding areas arranged in the one direction is defined and which is electrically connected to the display panel; and
a plurality of flexible circuit boards, each of which includes: one end disposed on a corresponding one of the panel bonding areas so as to be connected to the display panel; and
another end disposed on a corresponding one of the board bonding areas so as to be connected to the printed circuit board,
wherein each of at least two flexible circuit boards disposed at both ends in the one direction is tilted at a predetermined angle with a flexible circuit board adjacent thereto.

16. The display device of claim 15, wherein the display device has a shape curved in a direction surrounding a bending axis parallel to the first direction.

17. The display device of claim 16, wherein the printed circuit board is disposed under the display panel.

18. The display device of claim 17, wherein a magnitude of the predetermined angle is in inverse proportion to a distance between the display panel and the bending axis.

19. The display device of claim 15, wherein each of at least two panel bonding areas disposed at both ends among the panel bonding areas is tilted in such a way that it becomes closer to an end of the one edge of the display panel in the first direction as a distance from each side of the display panel in the one direction decreases.

20. The display device of claim 15, wherein panel bonding areas, disposed at both ends in the one direction, of the panel bonding areas are defined as outermost panel bonding areas,
wherein board bonding areas, disposed at both ends in the one direction, of the board bonding areas are defined as outermost board bonding areas, and
wherein a distance between each of the outermost panel bonding areas and a panel bonding area adjacent thereto is equal to a distance between each of the outermost board bonding areas and a board bonding area adjacent thereto.

21. A display panel comprising:
a plurality of pad electrodes disposed on one edge of the display panel in a first direction and arranged in a second direction perpendicular to the first direction,
wherein the pad electrodes comprises:
a plurality of first pad electrodes arranged in the second direction; and
at least one second pad electrode disposed at an outermost side of the first pad electrodes in the second direction,
wherein an extending direction of each of the first pad electrodes is different from an extending direction of the second pad electrode.

22. A printed circuit board comprising:
a plurality of pad electrodes disposed on one edge of the printed circuit board in a first direction and arranged in a second direction perpendicular to the first direction,
wherein the pad electrodes comprises:
a plurality of third pad electrodes arranged in the second direction; and
at least one fourth pad electrode disposed at an outermost side of the third pad electrodes in the second direction,
wherein an extending direction of each of the third pad electrodes is different from an extending direction of the fourth pad electrode.
